(19) United States
(12) Patent Application Publication
(10) Pub. No.: US 2025/0279373 A1
(43) Pub. Date: Sep. 4, 2025

(54) SEMICONDUCTOR DEVICE AND A METHOD OF MANUFACTURING THE SAME

(71) Applicant: Samsung Electronics Co., Ltd., Suwon-si (KR)

(72) Inventor: Donghoon Won, Suwon-si (KR)

(73) Assignee: Samsung Electronics Co., Ltd., Suwon-si (KR)

(21) Appl. No.: 18/937,620

(22) Filed: Nov. 5, 2024

(30) Foreign Application Priority Data
Mar. 4, 2024 (KR) 10-2024-0030712

(51) Int. Cl. H01L 23/00; H01L 25/065; H10B 80/00

(52) U.S. Cl. CPC H01L 23/562; H01L 24/02; H01L 24/08; H01L 24/94; H10B 80/00; H01L 25/0657; H01L 2224/02235; H01L 2224/08145; H01L 2224/94; H01L 2225/06562

(57) ABSTRACT

Some embodiments of the present disclosure relate to a semiconductor device including a first semiconductor chip comprising a first bonding pad and one or more first dummy pads; and a second semiconductor chip, positioned on the first semiconductor chip, comprising a second bonding pad and one or more second dummy patterns; wherein the first bonding pad is in contact with the second bonding pad, the first dummy pattern is in contact with the second dummy pattern, the first dummy pattern is positioned at an edge of the first semiconductor chip configured to be exposed from a side surface of the first semiconductor chip, and the second dummy pattern is positioned at an edge of the second semiconductor chip configured to be exposed to a side surface of the second semiconductor chip.

### CROSS-REFERENCE TO RELATED APPLICATIONS

This application claims priority to and the benefit under 35 U.S.C. § 119(a)-(d) of Korean Patent Application No. 10-2024-0030712 filed on Mar. 4, 2024, in the Korean Intellectual Property Office, the entire contents of which are incorporated herein by reference.

### FIELD

The present disclosure relates to a semiconductor device and a method for manufacturing the same.

### BACKGROUND

Wafer-to-wafer bonding is a technology of compressing the upper wafer and the lower wafer and then annealing them to directly bond them without a separate connection structure such as a solder bump. Wafer-to-wafer bonding enables thinning, high performance, and higher integration of semiconductor devices, and has an advantage of dramatically reducing the number of manufacturing processes.

This wafer-to-wafer bonding technology may be applied, for example, to semiconductor devices for storing high-capacity data in electronic systems that require data storage. For more specific example, wafer-to-wafer bonding technology may be applied to a semiconductor device including three-dimensionally arranged memory cells which are proposed instead of two-dimensionally arranged memory cells to increase the data storage capacity of the semiconductor device.

Meanwhile, a wafer-to-wafer structure in which an upper wafer and a lower wafer are bonded to each other may be separated into individual semiconductor devices including an upper chip and a lower chip through a dicing process. In such dicing process, delamination, cracks, etc. may occur between the upper and lower chips due to external force applied to the scribe lane region.

### SUMMARY

The present disclosure is to provide a semiconductor device capable of increasing junction force between the upper chip and the lower chip and preventing defects such as delamination and cracks in semiconductor devices manufactured by wafer-to-wafer bonding.

The present disclosure provides, as an embodiment, a semiconductor device including a first semiconductor chip including a first bonding pad and one or more first dummy pattern; and a second semiconductor chip positioned on the first semiconductor chip, the second semiconductor chip comprising a second bonding pad and one or more second dummy pattern; wherein the first bonding pad contacts the second bonding pad, the first dummy pattern contacts the second dummy pattern, the first dummy pattern is positioned at an edge of the first semiconductor chip and configured to be exposed from a side surface of the first semiconductor chip, and the second dummy pattern is positioned at an edge of the second semiconductor chip and configured to be exposed to a side surface of the second semiconductor chip.

The present disclosure provides, as another embodiment, a semiconductor device including a peripheral circuit chip including a plurality of first wiring layers, a plurality of first bonding pads electrically connected to the plurality of first wiring layers, and one or more first dummy patterns; and a memory chip positioned on the peripheral circuit chip, the memory chip comprising a common source line, a plurality of word lines positioned between the common source line and the peripheral circuit chip, a plurality of channel structures penetrating the plurality of word lines, a plurality of second wiring layers electrically connected to the plurality of word lines and the plurality of channel structures, a plurality of second bonding pads electrically connected to the plurality of second wiring layers, and one or more second dummy patterns, wherein the plurality of first bonding pads contact the plurality of second bonding pads, the first dummy pattern contacts the second dummy pattern, the first dummy pattern is positioned at an edge of the peripheral circuit chip and configured to be exposed from a side surface of the peripheral circuit chip, and the second dummy pattern is positioned at an edge of the memory chip and configured to be exposed to a side surface of the memory chip.

The present disclosure provides, as another embodiment, a semiconductor device manufacturing method including: preparing a first wafer including a first bonding pad and a first dummy pattern; preparing a second wafer including a second bonding pad and a second dummy pattern; bonding the first wafer and the second wafer so that the first bonding pad contacts the second bonding pad and the first dummy pattern contacts the second dummy pattern; and laser processing the first wafer and the second wafer along between a scribe lane area, wherein at least a part of each of the first dummy pattern and the second dummy pattern is positioned in the scribe lane area to be processed by the laser processing.

According to one aspect of the present disclosure, in a semiconductor device manufactured by wafer-to-wafer bonding, junction force between an upper chip and a lower chip can be increased and defects such as peeling and cracking can be prevented.

### BRIEF DESCRIPTION OF THE DRAWINGS

FIG. 1 to FIG. 3 are drawings illustrating a region where the dummy pattern is formed and a region where dicing is performed according to some embodiments of the wafer.

FIG. 4 is a cross-sectional view of a semiconductor device in wafer state according to some embodiments.

FIG. 5 is a cross-sectional view of a semiconductor device according to some embodiments.

FIG. 6 illustrates a layout of a dummy pattern, according to some embodiments.

FIG. 7 illustrates another layout of the dummy pattern, according to some embodiments.

FIG. 8 is a cross-sectional view of a semiconductor device in wafer state according to some embodiments.

FIG. 9 is a cross-sectional view of a semiconductor device according to some embodiments.

FIG. 10 is a drawing illustrating the detailed configurations of the semiconductor device of FIG. 9, according to some embodiments.

FIG. 11 and FIG. 12 illustrate methods of manufacturing the semiconductor device of FIG. 5 by dicing of a wafer-to-wafer structure, according to some embodiments.

FIG. 13 to FIG. 15 illustrate other methods of manufacturing the semiconductor device of FIG. 5 by dicing of a wafer-to-wafer structure, according to some embodiments.

FIG. 16 is a drawing schematically illustrating an electronic system including a semiconductor device according to some embodiments.

FIG. 17 is a perspective view schematically illustrating an electronic system including a semiconductor device according to some embodiments.

FIG. 18 is a cross-sectional view schematically illustrating a semiconductor device according to some embodiments.

### DETAILED DESCRIPTION

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

Throughout the specification, when a part is said to be “connected” to another part, this includes not only “directly connected” but also “indirectly connected” through another member. In a similar sense, this includes being “physically connected” as well as being “electrically connected”. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element, or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-section view”, it means that a cross section of the target portion cut vertically is viewed from a side.

In addition, throughout the specification, sequential numbers such as first and second are used to distinguish a certain component from other components that are the same or similar to the component, and are not necessarily intended to refer to a specific component. Accordingly, a component referred to as a first component in a specific part of this specification may be referred to as a second component in other parts of this specification.

Additionally, throughout the specification, references to a single element include references to a plurality of the element, unless specifically stated to the contrary. For example, a reference to a single component may be used to mean not only for one component, but also for a plurality of components, such as two, three, or more.

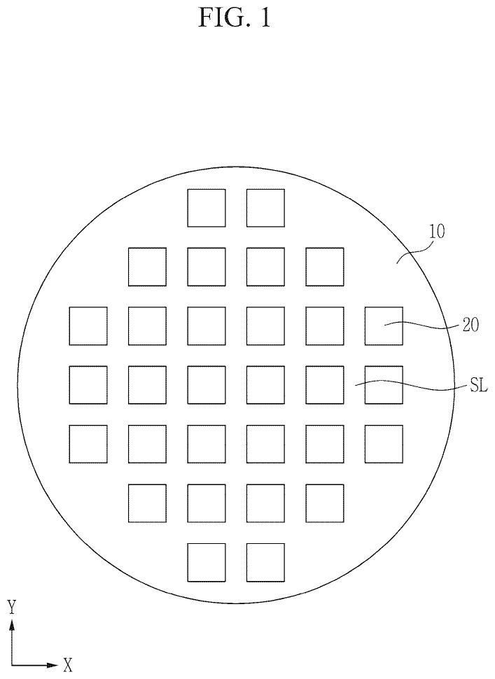

FIG. 1 to FIG. 3 are drawings illustrating a region where the dummy pattern is formed and a region where dicing is performed according to the present disclosure of the wafer.

Referring to FIG. 1, wafer 10 has chip regions 20 and a scribe lane region SL positioned between chip regions 20. In the chip region 20, known configurations such as a semiconductor substrate, circuit element(s) formed through FEOL (front end of line) and BEOL (back end of line) processes, wiring layer(s), interlayer insulating layer(s), and bonding pad(s) may exist. The scribe lane region SL is a gap between chip regions 20 for wafer dicing, and may prevent chip region 20 from being damaged during the dicing process by securing a clearance distance between chip regions 20. When dicing the wafer 10, the region that undergoes processing may be a region within the scribe lane region SL, and the scribe lane region SL may be wider than the region that undergoes processing.

The present disclosure intends to increase the junction force between the upper chips and the lower chips and generally prevent defects such as delamination and cracks by forming a dummy pattern 30 in the scribe lane area SL of each of the upper and lower chips in a semiconductor device manufactured by bonding two wafers 10 in a wafer-to-wafer manner.

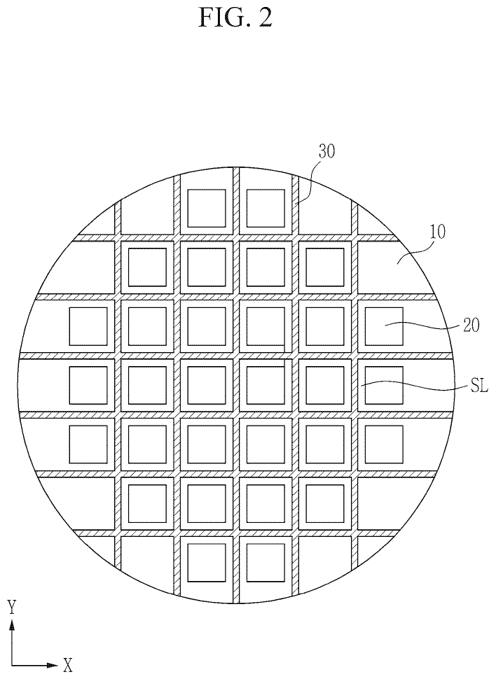

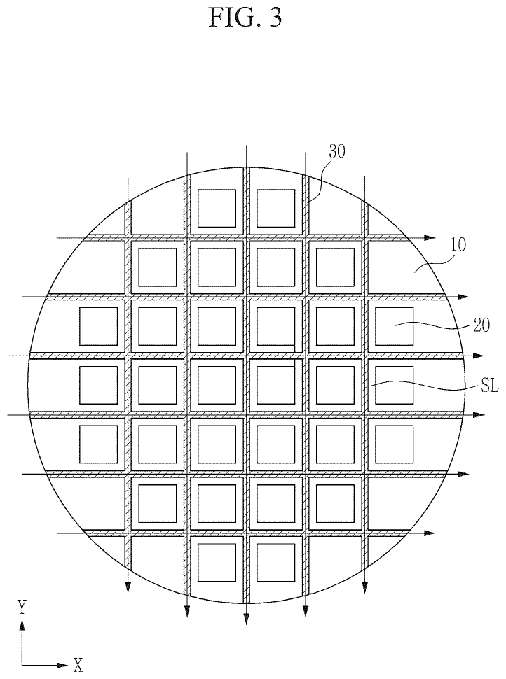

Referring to FIG. 2 and FIG. 3, a dummy pattern 30 according to some embodiments may be formed within the scribe lane region SL of wafer 10. For example, at least a part of the dummy pattern 30 may be positioned in an processed region of the scribe lane region SL of wafer 10. A processing direction and processed region of the wafer 10 are indicated by arrows in FIG. 3. When wafer-to-wafer bonding of two wafers 10, dummy patterns 30 may contact or bond to each other like bonding pads. When laser processing a wafer-to-wafer structure in which two wafers 10 are bonded, the dummy patterns 30 of the upper chip and lower chip may melted by heat and combined with each other. Therefore, according to the present disclosure, it is possible to provide a semiconductor device capable of increasing the junction force between the upper chips and lower chips and preventing defects such as delamination and cracks.

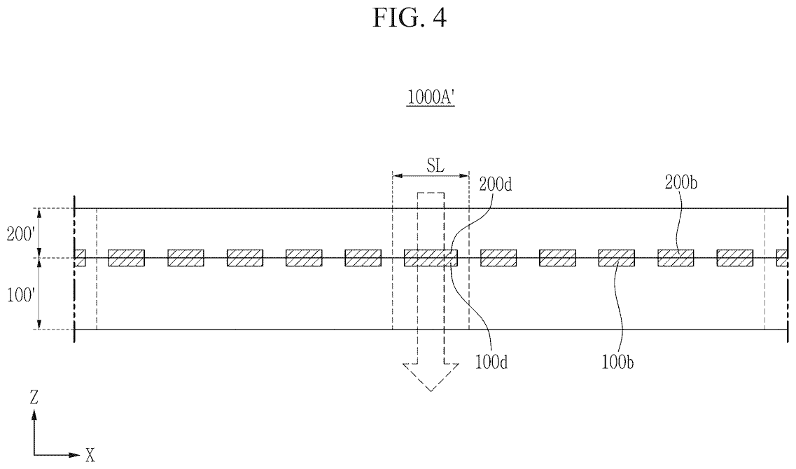

FIG. 4 is a cross-sectional view of a semiconductor device in wafer state according to some embodiments.

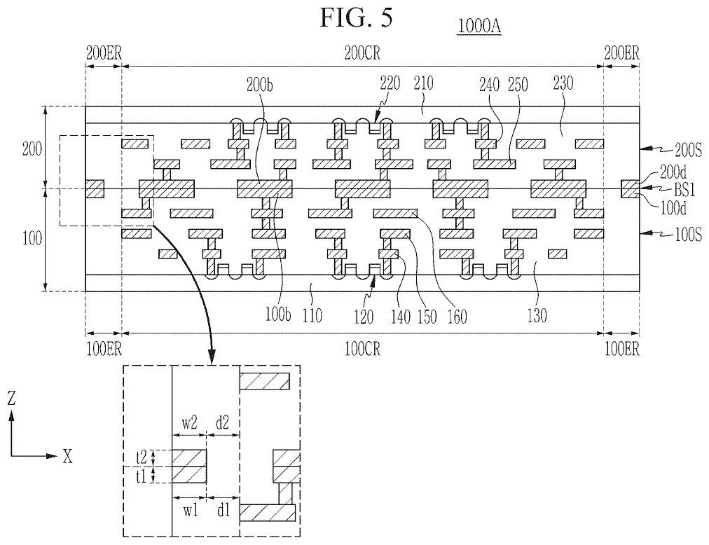

FIG. 5 is a cross-sectional view of a semiconductor device according to some embodiments.

First, referring to FIG. 5, a semiconductor device 1000A according to some embodiments includes a first semiconductor chip 100 and a second semiconductor chip 200 positioned on the first semiconductor chip 100.

The first semiconductor chip 100 may include a first substrate 110, a plurality of first circuit elements 120, a plurality of wiring layers 140, 150, and 160 electrically connected to the first circuit elements 120, a plurality of first bonding pads 100b electrically connected to a plurality of wiring layers 140, 150, and 160, and one or more first dummy patterns 100d. The number of components of the first semiconductor chip 100 may be changed depending on the design, and may, in some embodiments, be a single component or a plurality of components.

The first semiconductor chip 100 may include a first central region 110CR where the first circuit elements 120, wiring layers 140, 150, and 160, and the first bonding pad 100b are positioned, and a first peripheral area 100ER which at least partially surrounds the first central region 110CR and where the first dummy pattern 100d is positioned. In the present disclosure, the central region of a component and the peripheral area surrounding the central region are defined to distinguish different areas, and the central region and the peripheral area may not have a boundary visible to eyes.

The first substrate 110 may be a semiconductor substrate. The semiconductor substrate may include semiconductor compounds such as silicon (Si) and germanium (Ge), and/or compound semiconductors such as gallium arsenide (GaAs) and indium arsenide (InAs).

A plurality of first circuit elements 120 may be formed on the first substrate 110, and may include a metal oxide semiconductor field effect transistor (MOSFET) and a bipolar junction transistor (BJT), active elements, passive elements, etc. to form an integrated circuit (IC). The plurality of first circuit elements 120 may include a gate structure positioned between conductive regions.

The plurality of wiring layers 140, 150, and 160 may be electrically connected to the plurality of first circuit elements 120 and the first bonding pad 100b. Additionally, each of the plurality of wiring layers 140, 150, and 160 may be electrically connected to wiring layers positioned at other layers. Connections of each of the plurality of wiring layers 140, 150, and 160 to the first circuit elements 120 and the first bonding pad 100b, or connections between wiring layers positioned at other layers may be made by vias.

Each of the wiring layers 140, 150, and 160 may contain metal material, for example, copper (Cu), aluminum (Al), gold (Au), silver (Ag), cobalt (Co), nickel (Ni), lead (Pb), titanium (Ti), tungsten (W) or a combination thereof.

A first interlayer insulating layer 130 may be positioned between the plurality of first circuit elements 120 and the plurality of wiring layers 140, 150, 160, between the plurality of wiring layers 140, 150, 160, and between the plurality of wiring layers 140, 150, 160 and the first bonding pads 100b. The first interlayer insulating layer 130 may also be positioned between the plurality of wiring layers 140, 150, 160 and the first dummy pattern 100d. The first interlayer insulating layer 130 may include an insulating material, for example at least one of silicon oxide and silicon nitride.

The first bonding pad 100b may electrically connect the first semiconductor chip 100 to the second semiconductor chip 200. The first bonding pad 100b may be connected to the second bonding pad 200b, and may be bonded by contacting the second bonding pad 200b by wafer-to-wafer bonding.

The first dummy pattern 100d may improve the junction force between the first semiconductor chip 100 and the second semiconductor chip 200. The first dummy pattern 100d may be connected to the second dummy pattern 200d, and may be bonded by contacting the second dummy pattern 200d by wafer-to-wafer bonding. In addition, through the dicing process to be described later, the first dummy pattern 100d may be positioned at an edge of the first semiconductor chip 100 such that the first dummy pattern 100d is exposed from a side surface 100S of the first semiconductor chip 100.

The second semiconductor chip 200 may include a second substrate 210, a plurality of second circuit elements 220, a plurality of wiring layers 240 and 250 electrically connected to the plurality of second circuit elements 220, a plurality of second bonding pads 200b electrically connected to the plurality of wiring layers 240 and 250, and one or more second dummy patterns 200d. The number of components of the second semiconductor chip 200 may be changed depending on the design, and may, in some embodiments, be a single component or a plurality of components. In the drawing, the number of wiring layers 240 and 250 of the second semiconductor chip 200 is shown to be smaller than the number of wiring layers 140, 150, and 160 of the first semiconductor chip 100, but not limited thereto.

The second semiconductor chip 200 may include a second central region 200CR where the second circuit elements 220, wiring layers 240, and 250, and the second bonding pad 200b are positioned, and a second peripheral area 200ER which at least partially surrounds the second central region 200CR and where the second dummy pattern 200d is positioned.

The second substrate 210 may be a semiconductor substrate. The semiconductor substrate may include semiconductor compounds such as silicon (Si) and germanium (Ge), and/or compound semiconductors such as gallium arsenide (GaAs) and indium arsenide (InAs).

The plurality of second circuit elements 220 may be formed on the second substrate 210, and may include a metal oxide semiconductor field effect transistor (MOSFET) and a bipolar junction transistor (BJT), active elements, passive elements, etc. to form an integrated circuit (IC). The plurality of second circuit elements 220 may include a gate structure positioned between conductive regions.

The plurality of wiring layers 240, and 250 may be electrically connected to the plurality of second circuit elements 220 and the second bonding pad 200b. Also, each of the plurality of wiring layers 240 and 250 may be electrically connected to wiring layers positioned at other layers. Connections of each of the plurality of wiring layers 240, 250 to the second circuit elements 220 and the second bonding pad 200b, or connections between wiring layers positioned at different layers may be made by vias.

Each of the wiring layers 240 and 250 may contain metal material, for example, copper (Cu), aluminum (Al), gold (Au), silver (Ag), cobalt (Co), nickel (Ni), lead (Pb), titanium (Ti), tungsten (W) or a combination thereof.

A second interlayer insulating layer 230 may be positioned between the plurality of second circuit elements 220 and the plurality of wiring layers 240, 250, between the plurality of wiring layers 240, 250 and between the plurality of wiring layers 240, 250 and the second bonding pads 200b. The second interlayer insulating layer 230 may also be positioned between the plurality of wiring layers 240, 250 and the second dummy pattern 200d. The second interlayer insulating layer 230 may include an insulating material, for example at least one of silicon oxide and silicon nitride.

The second bonding pad 200b may electrically connect the second semiconductor chip 200 to the first semiconductor chip 100. The second bonding pad 200b may be connected to the first bonding pad 100b, and may be bonded by contacting the first bonding pad 100b by wafer-to-wafer bonding.

The second dummy pattern 200d may improve the junction force between the second semiconductor chip 200 and the first semiconductor chip 100. The second dummy pattern 200d may be connected to the first dummy pattern 100d, and may be bonded by contacting the first dummy pattern 100d by wafer-to-wafer bonding. In addition, through the dicing process to be described later, the second dummy pattern 200d may be positioned at an edge of the second semiconductor chip 200 such that the second dummy pattern 200d is exposed from a side surface 200S of the second semiconductor chip 200.

Referring to FIG. 4, the semiconductor device 1000A may be manufactured by dicing the wafer-to-wafer structure 1000A′, which is manufactured by wafer-to-wafer bonding the first wafer 100′ and the second wafer 200′, through laser processing to separate into individual semiconductor devices including the first semiconductor chip 100 and the second semiconductor chip 200.

Wafer-to-wafer bonding is a technology that directly bonds an upper wafer and a lower wafer, which are separately manufactured, without a separate connection structure such as a solder bump. For example, the bonding method may refer to a method of electrically connecting a bonding pad formed on the uppermost wiring layer of the upper chip and a bonding pad formed on the uppermost wiring layer of the lower chip. For example, in case that the bonding pad is made of copper (Cu), the bonding method may be a Cu—Cu bonding method. Wafer-to-wafer bonding may be performed by pressing the upper wafer and the lower wafer and then annealing them, but not limited thereto. Wafer-to-wafer bonding technology enables thinning, high performance, and higher integration of semiconductor devices, and has an advantage of dramatically reducing the number of manufacturing processes.

In the present disclosure, the first dummy pattern 100d and the second dummy pattern 200d are formed on bonding surfaces of first wafer 100′ and second wafer 200′, and within scribe lane region SL. When wafer-to-wafer bonding of the first wafer 100′ and the second wafer 200′, the first bonding pad 100b may be bonded by contacting the second bonding pad 200b, and the first dummy pattern 100d may be bonded by contacting the second dummy pattern 200d. Therefore, in the wafer-to-wafer structure 1000A′, the first bonding pad 100b may overlap the second bonding pad 200b, and the first dummy pattern 100d may overlap the second dummy pattern 200d on a plane. In this disclosure, for convenience of explanation, the same names and symbols were used for the dummy pattern in the wafer-to-wafer structure 1000A′ and the dummy pattern in the semiconductor device (a structure wherein a part of the dummy pattern of the wafer-to-wafer structure 1000A′ was removed through laser processing).

The width of the laser processed region (indicated by a dot lined arrow in FIG. 4) of the wafer-to-wafer structure (1000A′) may be narrower than the width of each of the first dummy patterns 100d and the second dummy patterns 200d in the X-direction. Therefore, the first dummy pattern 100d is positioned at an edge of the first semiconductor chip 100 such that the first dummy pattern 100d can be exposed from a side surface 100S of the first semiconductor chip 100, and the second dummy pattern 200d may be positioned at an edge of the second semiconductor chip 200 such that the second dummy pattern 200d can be exposed from a side surface 200S of the second semiconductor chip 200. The first dummy pattern 100d may form a part of the side surface 100S of the first semiconductor chip 100, and the second dummy pattern 200d may form a part of the side surface 200S of the second semiconductor chip 200. The first dummy pattern 100d and the second dummy pattern 200d remain in the first semiconductor chip 100 and the second semiconductor chip 200, respectively, which may further improve the junction force between the first semiconductor chip 100 and the second semiconductor chips 200 in the semiconductor device 1000A.

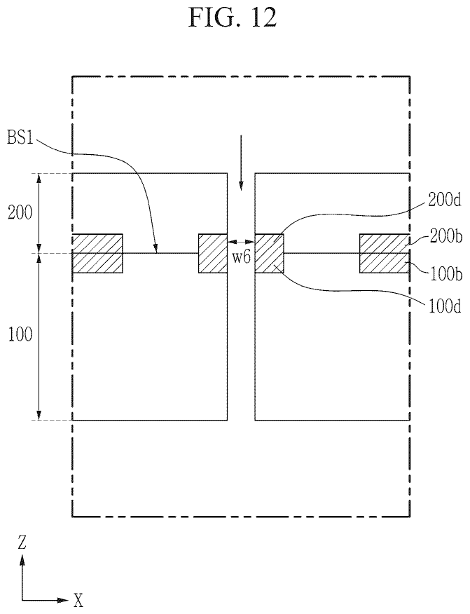

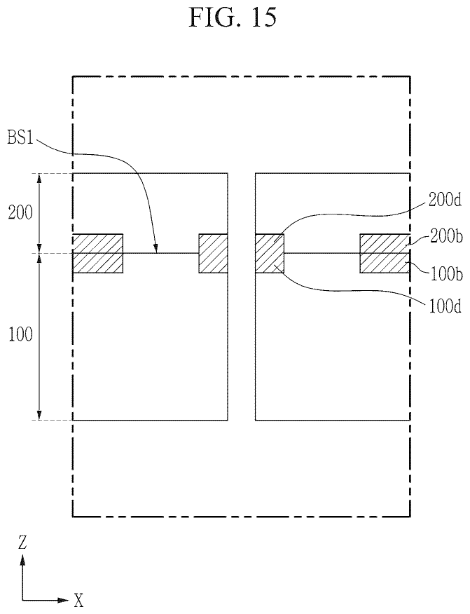

In at least a part of the interface BS1 between the first semiconductor chip 100 and the second semiconductor chip 200, the first dummy pattern 100d and the second dummy pattern 200d may have no boundary. At least a part of each of the first dummy pattern 100d and the second dummy pattern 200d may be combined and integrated after melting during laser processing, and no boundary may exist between them. For example, in the entire interface BS1 of the first semiconductor chip 100 and the second semiconductor chip 200, the first dummy pattern 100d and the second dummy pattern 200d may have no boundary (see FIG. 12 and FIG. 15). However, depending on the material of the dummy patterns 100d and 200d, the process conditions of laser processing, etc., the first dummy pattern 100d and the second dummy pattern 200d have a boundary in at least a part of the interface BS1 of the first semiconductor chip 100 and the second semiconductor chip 200.

For easily combining the first dummy pattern 100d and the second dummy pattern 200d, a material having a low melting point may be used as the material for the first dummy pattern 100d and/or the second dummy pattern 200d. In some embodiments, the melting points of the first dummy pattern 100d and the second dummy pattern 200d may be equal to or lower than the melting points of the first bonding pad 100b and the second bonding pad 200b. As a more specific example, copper (Cu) may be used as the material for the first bonding pad 100b and second bonding pad 200b, and copper (Cu), aluminum (Al), etc. may be used as the material for the first dummy pattern 100d and the second dummy pattern 200d.

The first dummy pattern 100d may be formed in the same process stage as the first bonding pad 100b, and the second dummy pattern 200d may be formed in the same process stage as the second bonding pad 200b. Therefore, the first dummy pattern 100d may be positioned at substantially the same level as the first bonding pad 100b, and the second dummy pattern 200d may be positioned at substantially the same level as the second bonding pad 200b. In this specification, “certain components are positioned at the ‘substantially’ same level” refers not only to a case where the first dummy pattern 100d and the first bonding pad 100b (and/or the second dummy pattern 200d and the second bonding pad 200b) are positioned at the same level, but also to a case where the components have a level difference that is relatively fine (e.g., small) due to an error in processes. Also, in this specification, meaning of “certain components are positioned at the same ‘level’” includes a case that a surface or the other surface opposite thereto of each of the components are positioned at the same level.

From a similar perspective, the first dummy pattern 100d may include the same material as the first bonding pad 100b, and the second dummy pattern 200d may include the same material as the second bonding pad 200b. For example, copper (Cu) or aluminum (Al) may be used as the material for first bonding pad 100b, second bonding pad 200b, first dummy pattern 100d, and/or second dummy pattern 200d.

Referring to FIG. 5 again, the distance d1 between the first dummy pattern 100d and the first central region 110CR and the distance d2 between the second dummy pattern 200d and the second central region 200CR may be 10 μm or more, respectively. In order to prevent the main components (circuit elements 120, 220, wiring layers 140, 150, 160, 240, 250, bonding pads 100b, 200b, etc.), which is positioned in the first central region 100CR and the second central region 200CR for operating the semiconductor device, from thermal damages due to the heat conducted to the dummy patterns 100d and 200d during laser processing, it may be desirable to separate the dummy patterns 100d and 200d from the main components with a certain distance.

The width w1 of the first dummy pattern 100d and the width w2 of the second dummy pattern 200d respectively may be 7 μm or more and 13 μm or less, 8 μm or more and 12 μm or less, 9 μm or more and 11 μm or less, 9.5 μm or more and 10.5 μm or less, or 10 μm. The width w1 of the first dummy pattern 100d means the length in a direction perpendicular to the side surface 100S of the first semiconductor chip 100, and the width w2 of the second dummy pattern 200d means the length in a direction perpendicular to the side surface 200S of the second semiconductor chip 200. For example, in a cross-sectional view on X-Z plane of FIG. 5, the width of each of the first dummy pattern 100d and the second dummy pattern 200d means a width in the X direction. The widths of each of the first dummy pattern 100d and the second dummy pattern 200d may be within the above-described range so that the processing width during dicing processes allows for sufficient adhesion between the first dummy pattern 100d and the second dummy pattern 200d and an appropriate distance between the dummy patterns 100d, 200d and the central regions 100CR, 200CR.

The thickness t1 of the first dummy pattern 100d and the thickness t2 of the second dummy pattern 200d may each be 5 μm or more, respectively. In order to secure sufficient junction force between the first dummy pattern 100d and the second dummy pattern 200d, and thereby to preventing defects such as delamination and cracks between the first semiconductor chip 100 and the second semiconductor chip 200, it may be desirable for the thickness of each of the first dummy pattern 100d and the second dummy pattern 200d to be within the above-described range.

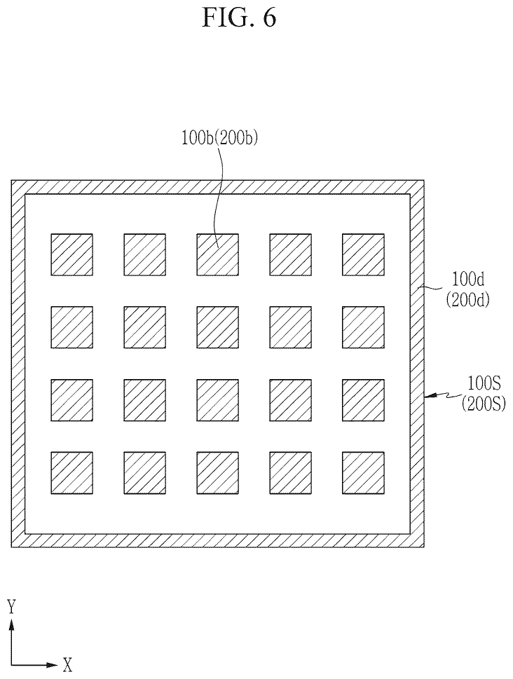

FIG. 6 illustrates a layout of a dummy pattern.

The first dummy pattern 100d and the second dummy pattern 200d may be positioned continuously along the edges of the first semiconductor chip 100 and the second semiconductor chip 200, respectively. In some embodiments, forming the first dummy pattern 100d and the second dummy pattern 200d continuously along a processing direction in the scribe lane area SL may form a single first dummy pattern 100d and a single second dummy pattern 200d continuously positioned along the edges of the first semiconductor chip 100 and the second semiconductor chip 200.

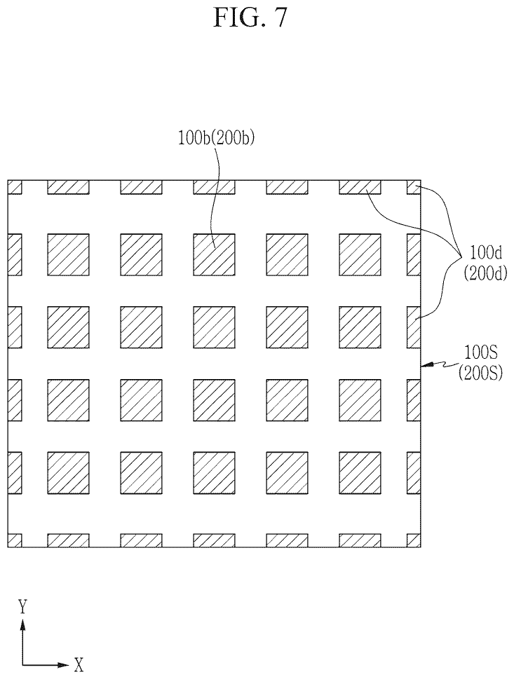

FIG. 7 illustrates another embodiment layout of the dummy pattern.

The first dummy patterns 100d and second dummy patterns 200d may be positioned discontinuously along the edges of first semiconductor chip 100 and second semiconductor chip 200, respectively. In some embodiments, forming the first dummy pattern 100d and the second dummy pattern 200d discontinuously along the processing direction in the scribe lane area SL may form a plurality of first dummy patterns 100d and second dummy patterns 200d positioned discontinuously along the edges of the first semiconductor chip 100 and the second semiconductor chip 200.

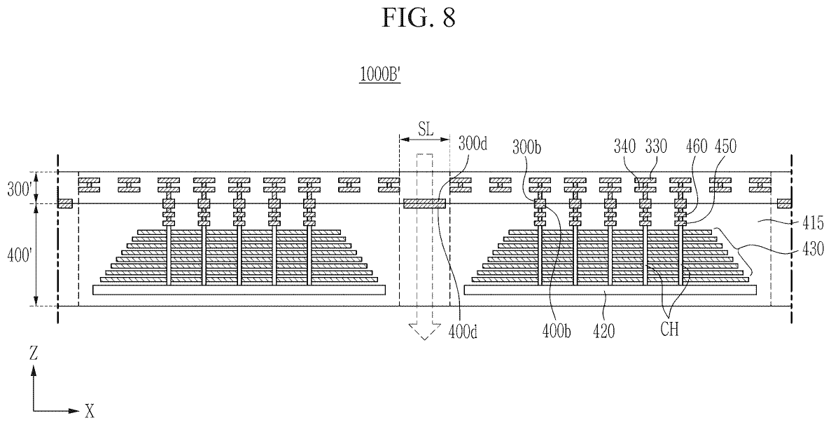

FIG. 8 is a cross-sectional view of a semiconductor device in wafer state according to some embodiments.

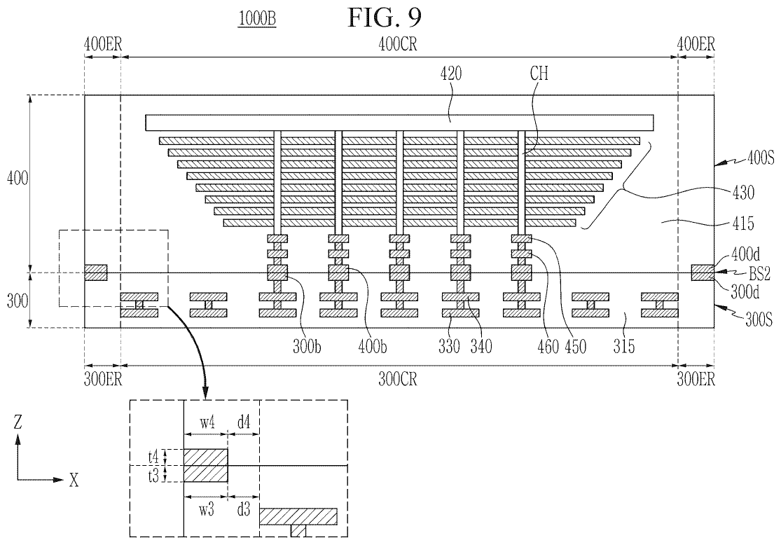

FIG. 9 is a cross-sectional view of a semiconductor device according to some embodiments.

FIG. 8 and FIG. 9 shows some embodiments in which the dummy patterns of the present disclosure are applied to memory semiconductor devices such as NAND flash.

First, referring to FIG. 9, the semiconductor device 1000B according to some embodiments includes a peripheral circuit chip 300 and a memory chip 400 positioned on the peripheral circuit chip 300.

The peripheral circuit chip 300 may include a plurality of wiring layers 330 and 340, a plurality of first bonding pads 300b electrically connected to the plurality of wiring layers 330 and 340, and one or more first dummy patterns 300d. The number of components of the peripheral circuit chip 300 may be changed depending on the design, and may, in some embodiments, be a single component or a plurality of components.

In addition, the peripheral circuit chip 300 may have a first central region 300CR where the plurality of wiring layers 330, and 340 and a plurality of first bonding pads 300b are positioned, and a first peripheral area 300ER which at least partially surrounds the first central region 300CR and where the first dummy pattern 300d is positioned.

The plurality of wiring layers 330, and 340 may serve as a peripheral wiring and may be electrically connected to each other through vias or electrically connected to the first bonding pads 300b.

The plurality of the wiring layers 330 and 340 may contain metal material, for example, copper (Cu), aluminum (Al), gold (Au), silver (Ag), cobalt (Co), nickel (Ni), lead (Pb), titanium (Ti), tungsten (W) or a combination thereof.

A first interlayer insulating layer 315 may be positioned between the plurality of wiring layers 330 and 340, and between the plurality of wiring layers 330 and 340 and the first bonding pads 300b. The first interlayer insulating layer 315 may also be positioned between the plurality of wiring layers 330, 340 and the first dummy pattern 300d. The first interlayer insulating layer 315 may include an insulating material, for example at least one of silicon oxide and silicon nitride.

The first bonding pad 300b may electrically connect the peripheral circuit chip 300 to the memory chip 400. The first bonding pad 300b may be connected to the second bonding pad 400b, and may be bonded by contacting the second bonding pad 400b by wafer-to-wafer bonding.

The first dummy pattern 300d may improve the junction force between the peripheral circuit chip 300 and the memory chip 400. The first dummy pattern 300d may be connected to the second dummy pattern 400d, and may be bonded by contacting the second dummy pattern 400d by wafer-to-wafer bonding. In addition, through the dicing process to be described later, the first dummy pattern 300d may be positioned at an edge of the peripheral circuit chip 300 such that the first dummy pattern 300d can be exposed from a side surface 300S of the peripheral circuit chip 300.

The memory chip 400 may include a common source line 420, a plurality of word lines 430 positioned between the common source line 420 and the peripheral circuit chip 300, a plurality of channel structures CH penetrating the plurality of word lines 430, a plurality of wiring layers 450, 460 electrically connected to the plurality of word lines 430 and the plurality of channel structures CH, a plurality of second bonding pads 400b electrically connected to the plurality of wiring layers 450, 460 and one or more second dummy patterns 400d. The number of components of the memory chip 400 may be changed depending on the design, and may, in some embodiments, be a single component or a plurality of components.

In addition, the memory chip 400 may have a second central region 400CR where the common source line 420, a plurality of word lines 430, a plurality of channel structures CH, a plurality of wiring layers 450 and 460, and a plurality of second bonding pads 400b are positioned, and a second peripheral area 400ER which at least partially surrounds the second central region 400CR and where the second dummy pattern 400d is positioned. The second central region 400CR and the second peripheral area 400ER may be divided based on the outermost component among the above-described components included in the second central region 400CR. While the width of the second peripheral area 400ER is shown to be the same as the width of the first peripheral area 300ER in the drawing, it is an example, and the width of the second peripheral area 400ER and the width of the first peripheral area 300ER may be different.

The second bonding pad 400b may electrically connect the memory chip 400 with the peripheral circuit chip 300. The second bonding pad 400b may be connected to the first bonding pad 300b, and may be bonded by contacting the first bonding pad 300b by wafer-to-wafer bonding.

The second dummy pattern 400d may improve the junction force between the memory chip 400 and the peripheral circuit chip 300. The second dummy pattern 400d may be connected to the first dummy pattern 300d, and may be bonded by contacting the first dummy pattern 300d by wafer-to-wafer bonding. In addition, through the dicing process to be described later, the second dummy pattern 400d may be positioned at an edge of the memory chip 400 such that the second dummy pattern 400d can be exposed from a side surface 400S of the memory chip 400.

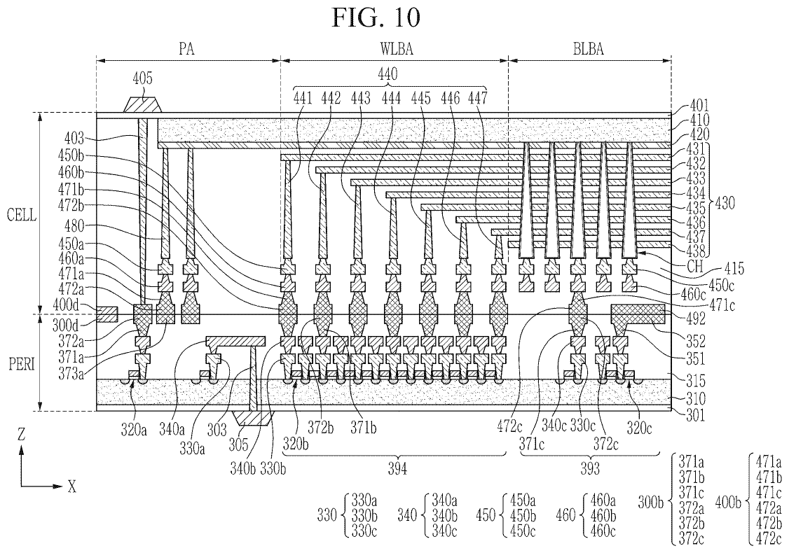

The common source line 420, the plurality of word lines 430, the channel structures CH, the plurality of wiring layers 450, and 460 will be described in more detail along with other detailed configurations of the semiconductor device in the description for FIG. 10.

Referring to FIG. 8, the semiconductor device 1000B may be manufactured by dicing the wafer-to-wafer structure 1000B′, which is manufactured by wafer-to-wafer bonding the first wafer 300′ and the second wafer 400′, through laser processing to separate into individual semiconductor devices including the peripheral circuit 300 and the memory chip 400.

In the present disclosure, the first dummy pattern 300d and the second dummy pattern 400d are formed at the bonding surface of first wafer 300′ and second wafer 400′, and within the scribe lane region SL. When wafer-to-wafer bonding of the first wafer 300′ and the second wafer 400′, the plurality of first bonding pads 300b may be in contact with the plurality of second bonding pads 400b such that the plurality of first bonding pads 300b and the plurality of second bonding pads 400b are bonded, and the dummy pattern 300d may be in contact with the second dummy pattern 400d such that the first dummy pattern 300d and the second dummy pattern 400d are bonded. Therefore, in the wafer-to-wafer structure 1000B′, the first bonding pad 300b may overlap the second bonding pad 400b, and the first dummy pattern 300d may overlap the second dummy pattern 400d on a plane.

The width of the laser processed region (indicated by a dot lined arrow in FIG. 8) of the wafer-to-wafer structure 1000B′ may be narrower than the width of each of the first dummy patterns 300d and the second dummy patterns 400d in the X-direction. Therefore, the first dummy pattern 300d is positioned at an edge of the peripheral circuit 300 such that the first dummy pattern 300d can be exposed from a side surface 300S of the peripheral circuit chip 300, and the second dummy pattern 400d may be positioned at an edge of the memory chip 400 such that the second dummy pattern 400d can be exposed from a side surface 400S of the memory chip 400. The first dummy pattern 300d may form a part of the side surface 300S of the peripheral circuit chip 300, and the second dummy pattern 400d may form a part of the side surface 400S of the memory chip 400. The first dummy pattern 300d and the second dummy pattern 400d remain in the peripheral circuit chip 300 and the second memory chip 400, respectively, which may further improve the junction force between the peripheral circuit chip 300 and the memory tor chips 400 in the semiconductor device 1000B.

In at least some of the interface BS2 between the peripheral circuit chip 300 and the memory chip 400, the first dummy pattern 300d and the second dummy pattern 400d may have no boundary. At least a part of each of the first dummy pattern 300d and the second dummy pattern 400d may be combined and integrated after melting in laser processing, and no boundary may exist between them. For example, in the entire interface BS2 between the peripheral circuit chip 300 and the memory chip 400, the first dummy pattern 300d and the second dummy pattern 400d may have no boundary. However, in some embodiments, depending on the material of the dummy patterns 300d and 400d, the process conditions of laser processing, etc., the first dummy pattern 300d and the second dummy pattern 400d have a boundary in at least a part of the interface BS2 of the peripheral circuit chip 300 and the memory chip 400.

For the ease of joining the first dummy pattern 300d and the second dummy pattern 400d, a material of low melting point may be used as the material for the first dummy pattern 300d and the second dummy pattern 400d. For example, the melting points of the first dummy pattern 300d and the second dummy pattern 400d may be equal to or lower than the melting points of the first bonding pad 300b and the second bonding pad 400b. As a more specific example, copper (Cu) may be used as the material for the first bonding pad 300b and second bonding pad 400b, and copper (Cu), aluminum (Al), etc. may be used as the material for the first dummy pattern 300d and the second dummy pattern 400d.

The first dummy pattern 300d may be formed in the same process stage as the first bonding pad 300b, and the second dummy pattern 400d may be formed in the same process stage as the second bonding pad 400b. Therefore, the first dummy pattern 300d may be positioned at substantially the same level as the first bonding pad 300b, and the second dummy pattern 400d may be positioned at substantially the same level as the second bonding pad 400b.

From a similar perspective, the first dummy pattern 300d may include the same material as the first bonding pad 300b, and the second dummy pattern 400d may include the same material as the second bonding pad 400b. For example, copper (Cu) or aluminum (Al) may be used as the material for first bonding pad 300b, second bonding pad 400b, first dummy pattern 300d, and second dummy pattern 400d.

Referring to FIG. 9 again, the distance d3 between the first dummy pattern 300d and the first central region 300CR and the distance d4 between the second dummy pattern 400d and the second central region 400CR may be 10 μm or more, respectively. In order to prevent the main components (wiring layers 330, 340, first bonding pads 300b, common source line 420, word lines 430, channel structures (CH), wiring layers 450 and 460, second bonding pads 400b, etc.), which are positioned in the first central region 300CR and the second central region 400CR for operating the semiconductor device, from thermal damages due to the heat conducted to the dummy patterns 100d and 200d during laser processing, it may be desirable to separate the dummy patterns 300d and 400d from the main components with a certain distance.

The width w3 of the first dummy pattern 300d and the width w4 of the second dummy pattern 400d respectively may be 7 μm or more and 13 μm or less, 8 μm or more and 12 μm or less, 9 μm or more and 11 μm or less, 9.5 μm or more and 10.5 μm or less, or 10 μm. The width w3 of the first dummy pattern 300d means the length in a direction perpendicular to the side surface 300S of the peripheral circuit chip 300, and the width w4 of the second dummy pattern 400d means the length in a direction perpendicular to the side surface 400S of the memory chip 400. For example, in a cross-sectional view on X-Z plane of FIG. 5, the width of each of the first dummy pattern 300d and the second dummy pattern 400d means a width in the X direction. The widths of each of the first dummy pattern 300d and the second dummy pattern 400d may be within the above-described range so that the processing width during dicing processes allow for sufficient adhesion between the first dummy pattern 300d and the second dummy pattern 400d and an appropriate distance between the dummy patterns 300d, 400d and the central regions 300CR, 400CR.

The thickness t3 of the first dummy pattern 300d and the thickness t4 of the second dummy pattern 400d may each be 5 μm or more, respectively. In order to secure sufficient junction force between the first dummy pattern 300d and the second dummy pattern 400d, thereby preventing defects such as delamination and cracks between the peripheral circuit chip 300 and the memory chip 400, it may be desirable for the thickness of each of the first dummy pattern 300d and the second dummy pattern 400d to be within the above-described range.

FIG. 10 is a drawing illustrating the detailed configurations of the semiconductor device of FIG. 9.

The peripheral circuit region (PERI) and the cell region (CELL) of FIG. 10 may respectively correspond to peripheral circuit chip 300 and memory chip 400 of FIG. 9.

In FIG. 10, sub-codes are used for the components included in the external pad bonding region (PA), word line bonding region (WLBA), and bit line bonding region (BLBA). For example, wiring layers 330a, 330b, and 330c are included in wiring layer 330, and wiring layers 340a, 340b, and 340c are included in wiring layer 340. Wiring layers 450a, 450b, and 450c are included in wiring layer 450, and wiring layers 460a, 460b, and 460c are included in wiring layer 460. Additionally, the first bonding pads 371a, 372a, 371b, 372b, 371c, 372c are included in the first bonding pad 300b, and the second bonding pads 471a, 472a, 471b, 472b, 471c, 472c are included in the second bonding pad 400b. The peripheral circuit region (PERI) may include a first substrate 310, an interlayer insulating layer 315, a plurality of circuit elements 320a, 320b, 320c formed on the first substrate 310, first wiring layers 330a, 330b, 300c respectively connected to the plurality of circuit elements 320a, 320b, 320c, and second wiring layers 340a, 340b, 340c formed on the first wiring layers 330a, 330b, 330c. In some embodiments, the first wiring layers 330a, 330b, 330c may be formed of tungsten having relatively high resistance, and the second wiring layers 340a, 340b, and 340c may be formed of copper having relatively low resistance.

It should be noted that while only the first wiring layers 330a, 330b, 330c and the second wiring layers 340a, 340b, 340c are shown and described in this specification, the present disclosure is not limited in this manner. For example, at least one or more wiring layers may be formed on the second wiring layers 340a, 340b, 340c. At least some of the one or more wiring layers formed on the second wiring layers 340a, 340b, 340c may be made of aluminum, etc., which has a resistance lower than copper that forms the second wiring layers 340a, 340b, 340c.

The interlayer insulating layer 315 is disposed on the first substrate 310 to cover the plurality of circuit elements 320a, 320b, 320c, first wiring layer 330a, 330b, 330c, and second wiring layer 340a, 340b, 340c, and may include insulating materials such as silicon oxide, silicon nitride, etc.

Lower bonding pads 371b and 372b may be formed on the second wiring layer 340b of the word line bonding region (WLBA). In the word line bonding region (WLBA), the lower bonding pads 371b, 372b of the peripheral circuit region (PERI) may be electrically connected to the upper bonding pads 471b, 472b of the cell region (CELL) by a bonding method, and the lower bonding pads 371b, 372b and upper bonding pads 471b, 472b may be formed of aluminum, copper, or tungsten, etc.

The cell region (CELL) may provide at least one memory block. The cell region (CELL) may include a second substrate 410 and a common source line 420. On the second substrate 410, a plurality of word lines 430 (431, 432, 433, 434, 435, 436, 437 and 438) may be stacked along the Z-axis direction perpendicular to the top surface of the second substrate 410. String selection lines and ground selection lines may be disposed respectively above and below the word lines 430, and a plurality of word lines 430 may be disposed between the string selection lines and the ground selection line.

In the bit line bonding region (BLBA), the channel structure (CH) extends in a direction perpendicular to the top surface of the second substrate 410 and may penetrate the word lines 430, string selection lines, and ground selection lines. The channel structure (CH) may include a data storage layer, a channel layer, and/or an embedded insulating layer. The channel layer may be electrically connected to the first wiring layer 450c and the second wiring layer 460c. For example, the first wiring layer 450c may be a bit line contact, and the second wiring layer 460c may be a bit line. In some embodiments, bit line 460c may extend along the Y direction parallel to the top surface of the second substrate 410.

In some embodiments, a region where the channel structure (CH) and bit line 460c are disposed may be defined as a bit line bonding region (BLBA). In the bit line bonding region (BLBA), the bit line 460c may be electrically connected to the circuit elements 320c providing page buffer 393 in the peripheral circuit region (PERI). For example, the bit line 460c may be connected to upper bonding pads 471c, 472c in the peripheral circuit region (PERI), and upper bonding pads 471c, 472c may be connected to the lower bonding pads 371c, 372c connected to circuit elements 320c of page buffer 393.

In the word line bonding region (WLBA), the word lines 430 may extend along the X direction parallel to the top surface of the second substrate 410 and may be connected to a plurality of cell contact plugs 440 (441, 442, 443, 444, 445, 446 and 447). The word lines 430 and the cell contact plugs 440 may be connected to each other at pads provided by extending at least some of the word lines 430 with different lengths along the X direction. The first wiring layer 450b and the second wiring layer 460b may be sequentially connected to the top of the cell contact plugs 440 connected to word lines 430. The cell contact plugs 440 may be connected to the peripheral circuit region (PERI) in the word line bonding region (WLBA), through the upper bonding pads 471b, 472b of the cell region (CELL) and the lower bonding pads 371b,372b of the peripheral circuit region (PERI).

The cell contact plugs 440 may be electrically connected to circuit elements 320b that provide providing a row decoder 394 in the peripheral circuit region (PERI). In some embodiments, an operating voltage of circuit elements 320b providing the row decoder 394 may be different from an operating voltage of circuit elements 320c providing the page buffer 393. For example, the operating voltage of circuit elements 320c providing page buffer 393 may be greater than the operating voltage of circuit elements 320b providing the row decoder 394.

A common source line contact plug 480 may be placed in the external pad bonding region (PA). The common source line contact plug 480 is made of a conductive material such as metal, metal compound, and/or polysilicon, and may be electrically connected to the common source line 420. A first wiring layer 450a and a second wiring layer 460a may be stacked sequentially on the top of the common source line contact plug 480. For example, a region where the common source line contact plug 480, first wiring layer 450a, and second wiring layer 460a are disposed may be defined as an external pad bonding region (PA).

Input/output pads 305, and 405 may be disposed in the external pad bonding region (PA). A lower insulating layer 301 covering the lower surface of the first substrate 310 may be formed below the first substrate 310, and a first input/output pad 305 may be formed on the lower insulating layer 301. The first input/output pad 305 is connected to at least one of the plurality of circuit elements 320a, 320b, 320c disposed in the peripheral circuit region (PERI) through the first input/output contact plug 303, and may be separated from the first substrate 310 by the lower insulating layer 301. In addition, a side insulating layer may be disposed between the first input/output contact plug 303 and the first substrate 310 to electrically separate the first input/output contact plug 303 from the first substrate 310.

An upper insulating layer 401 covering the top surface of the second substrate 410 may be formed on the top of the second substrate 410, and a second input/output pad 405 may be disposed on the upper insulating layer 401. The second input/output pad 405 may be connected to at least one of the plurality of circuit elements 320a, 320b, 320c disposed in the peripheral circuit region (PERI) through the second input/output contact plug 403.

In some embodiments, the second substrate 410 and the common source line 420 may not be disposed in a region where the second input/output contact plug 403 is disposed. Also, the second input/output pad 405 may not overlap the word lines 430 in a third direction (Z-axis direction). The second input/output contact plug 403 is separated from the second substrate 410 in a direction parallel to the top surface of the second substrate 410, and may penetrate the interlayer insulating layer 415 of the cell region (CELL) to be connected to the second input/output pad 405.

According to some embodiments, the first input/output pad 305 and the second input/output pad 405 may be formed selectively (e.g., individually). For example, the semiconductor device may include only the first input/output pad 305 disposed on the top of the first substrate 301, or may include only the second input/output pad 405 disposed on the top of the second substrate 401. Alternatively, the semiconductor device may include both the first input/output pad 305 and the second input/output pad 405.

In each of the external pad bonding region (PA) and bit line bonding region (BLBA) included in each of the cell region (CELL) and peripheral circuit region (PERI), a wiring pattern of the uppermost wiring layer may exist as a dummy pattern, or the uppermost wiring layer may be empty.

In the external pad bonding region (PA) of the semiconductor device, a lower wiring pattern 373a of the same shape as the upper wiring pattern 472a of the cell region (CELL) may be formed on the uppermost wiring layer of the peripheral circuit region (PERI), corresponding to upper wiring pattern 472a formed on the uppermost wiring layer of the cell region (CELL). The lower wiring pattern 373a formed on the uppermost wiring layer of the peripheral circuit region (PERI) may not be connected to a separate contact in the peripheral circuit region (PERI). Similarly, in the external pad bonding region (PA), a upper wiring pattern of the same shape as a lower wiring pattern of the peripheral circuit region (PERI) may be formed on the upper wiring layer of the cell region (CELL), corresponding to the lower wiring pattern formed on the uppermost wiring layer of the peripheral circuit region (PERI).

The lower bonding pads 371b, 372b may be formed on the second wiring layer 340b of the word line bonding region (WLBA). In the word line bonding region (WLBA), the lower bonding pads 371b and 372b of the peripheral circuit region (PERI) may be electrically connected to the upper bonding pads 471b and 472b of the cell region (CELL) by a bonding method.

Also, in the bit line bonding region (BLBA), a upper wiring pattern 492 of the same shape as a lower wiring pattern 352 of the peripheral circuit region (PERI) may be formed on the uppermost wiring layer of the cell region (CELL), corresponding to the lower wiring pattern 352 formed on the uppermost wiring layer of the peripheral circuit region (PERI). No contact may be formed on the upper wiring pattern 492 formed on the uppermost wiring layer of the cell region (CELL).

In some embodiments, a first dummy pattern 300d and a second dummy pattern 400d may be positioned at an edge of the external pad bonding region (PA). The edge of the external pad bonding region (PA) where the first dummy pattern 300d and the second dummy pattern 400d are positioned may correspond to the first peripheral area 300ER of the peripheral circuit chip 300 or the second peripheral area 400ER of the memory chip 400.

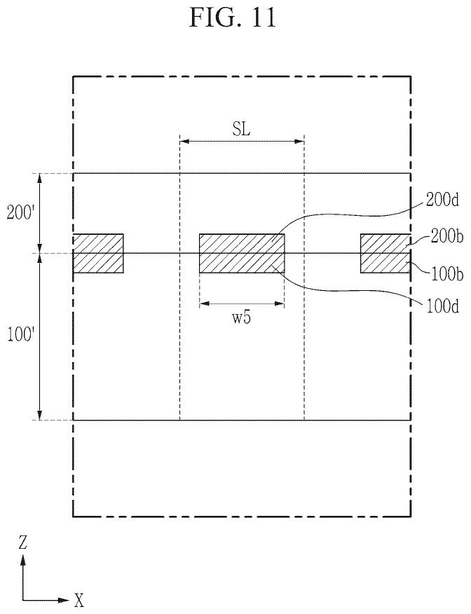

FIG. 11 and FIG. 12 illustrates methods of manufacturing the semiconductor device of FIG. 5 by dicing of a wafer-to-wafer structure.

For convenience, among the wafer-to-wafer structure, only a partial region including the first dummy pattern 100d and the second dummy pattern 200d is shown in the drawing.

The semiconductor device manufacturing method includes preparing a first wafer 100′ including a first bonding pad 100b and a first dummy pattern 100d, preparing a second wafer 200′ including a second bonding pad 200b and a second dummy pattern 200d, bonding the first wafer 100′ and the second wafer 200′ so that the first bonding pad 100b contacts the second bonding pad 200b and the first dummy pattern 100d contacts the second dummy pattern 200d, and laser processing the first wafer 100′ and the second wafer 200′ along between the scribe lane region SL.

Bonding the first wafer 100′ and the second wafer 200′ may be performed by wafer-to-wafer bonding. For example, bonding the first wafer 100′ and the second wafer 200′ may be performed by placing the first wafer 100′ and the second wafer 200′ so that the first bonding pad 100b and the second bonding pad 200b face each other and so that the first dummy pattern 100d and the second dummy pattern 200d face each other. The first wafer 100′ and the second wafer 200′ may then be pressed and annealed. By wafer-to-wafer bonding, the first bonding pad 100b may be bonded by contacting the second bonding pad 200b, and the first dummy pattern 100d may be bonded by contacting the second dummy pattern 200d.

In a wafer-to-wafer structure, the width w5 of the first dummy pattern 100d and the second dummy pattern 200d may be about 40 μm. Considering that some of the width (e.g., width w5) is removed during laser processing of the first dummy pattern 100d and the second dummy pattern 200d, it is preferable to control the width w5 of the first dummy pattern 100d and the second dummy pattern 200d to the above-mentioned range before laser processing such that sufficient junction force between the dummy patterns.

In some embodiments, the laser processing of first wafer 100′ and second wafer 200′ may involve laser processing the first wafer 100′ and second wafer 200′ entirely in their thickness direction.

In laser processing the first wafer 100′ and second wafer 200′, at least a part of each of the first dummy pattern 100d and the second dummy pattern 200d is positioned within the scribe lane region SL such that the first dummy pattern 100d and the second dummy pattern 200d is processed by laser processing. At least a part of each of the first dummy pattern 100d and the second dummy pattern 200d may be combined after melting in laser processing, and the junction force between the first semiconductor chip 100 and the second semiconductor chip 200 may be improved.

In laser processing first wafer 100′ and second wafer 200′, the width w6 the first wafer 100′ and second wafer 200′ processed with laser may be 20 μm or less. The width w6 of which the first wafer 100′ and second wafer 200′ are processed with laser corresponds to the widths of which the first dummy pattern 100d and the second dummy pattern 200d are removed in laser processing. Therefore, after laser processing, a part of the first dummy pattern 100d may remain in the first wafer 100′, and a part of the second dummy pattern 200d may remain in the second wafer 200′. The first dummy pattern 100d and the second dummy pattern 200d remain in the first semiconductor chip 100 and the second semiconductor chip 200, respectively, which may further improve the junction force between the first semiconductor chip 100 and the second semiconductor chips 200 in the semiconductor device 1000A.

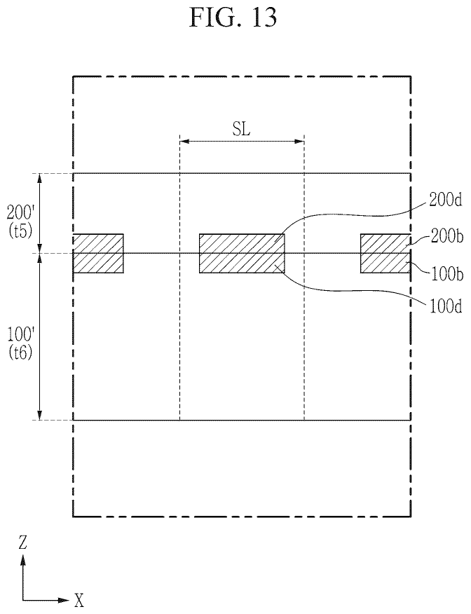

FIG. 13 to FIG. 15 illustrate other methods of manufacturing the semiconductor device of FIG. 5 by dicing of a wafer-to-wafer structure.

For convenience, in the wafer-to-wafer structure, only a partial region including the first dummy pattern 100d and the second dummy pattern 200d is shown in the drawing.

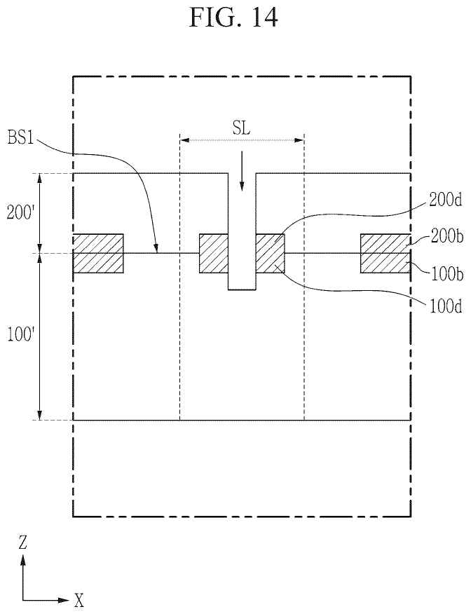

In some embodiments, laser processing the first wafer 100′ and the second wafer 200′ involves laser processing the entire second wafer 200′ in a thickness direction (Z-direction) and further processing a part of the first wafer 100′ in the thickness direction (Z-direction). In some embodiments, it is preferable to perform laser processing at least to a depth where the interface between the first dummy pattern 100d and the second dummy pattern 200d is positioned, such that the first dummy pattern 100d and the second dummy pattern 200d are combined after melting. For example, as shown in FIG. 14, during laser processing, the entire first dummy pattern 100d and second dummy pattern 200d may be processed in a thickness direction (Z-direction) respectively. In some embodiments, during laser processing, the entire second dummy pattern 200d may be processed in the thickness direction (Z-direction), and only a part of the first dummy pattern 100d may be processed in the thickness direction (Z-direction).

In addition, the semiconductor device manufacturing method according to some embodiments further comprises blade processing the remaining part of the first wafer 100′ in the thickness direction (Z-direction). By laser processing only a part of the wafer-to-wafer structure in the thickness direction and blade processing the remaining part, processing time may be reduced, and productivity may be improved.

The thickness t5 of which the second wafer 200′ is entirely processed in the thickness direction (Z direction) by laser may be thinner than the thickness t6 of the first wafer 100′. By performing laser processing on the second wafer 200′ having a thinner thickness, the time required for laser processing the first dummy pattern 100d and the second dummy pattern 200d may be reduced.

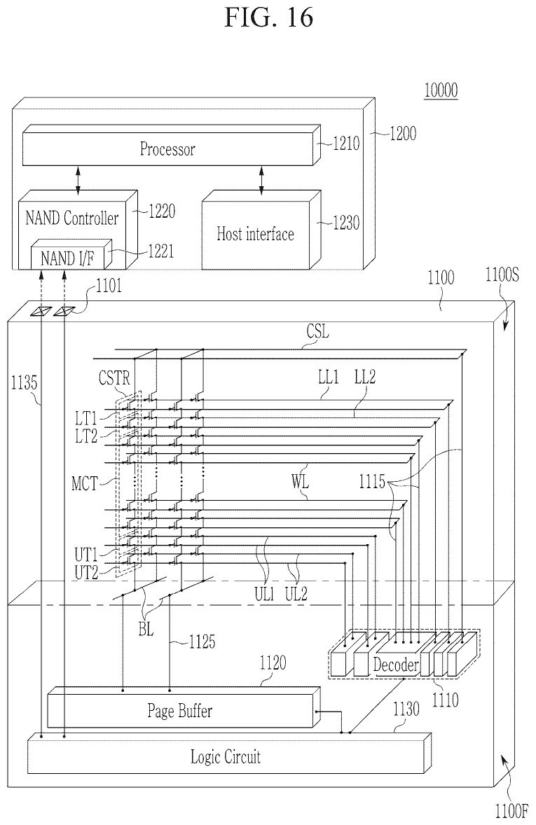

Hereinafter, referring to FIG. 16 to FIG. 18, an example of an electronic system including a semiconductor device described above will be described.

FIG. 16 is a drawing schematically illustrating an electronic system including a semiconductor device according to some embodiments.

Referring to FIG. 16, the electronic system 10000 may include a semiconductor device 1100 and a controller 1200 electrically connected to the semiconductor device 1100. The electronic system 10000 may be a storage device including one or a plurality of semiconductor devices 1100 or an electronic device including a storage device. For example, the electronic system 10000 may be a solid state drive device (SSD) device, a universal serial bus (USB), a computing system, a medical device, or a communication device, which includes one or plurality of semiconductor devices 1100.

The semiconductor device 1100 may be a non-volatile memory device, for example, may be the NAND flash memory device described above referring to FIG. 9. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bit line BL, a common source line CSL, a word lines WL, first and second gate upper lines UL1, and UL2, first and second gate lower lines LL1, and LL2, and memory cell strings CSTR between the bit line BL and the common source line CSL.

In the second structure 1100S, each memory cell string CSTR may include lower transistors LT1, and LT2 adjacent to the common source line CSL, upper transistors UT1, and UT2 adjacent to the bit line BL, and memory cell transistors MCT disposed between the lower transistors LT1, and LT2 and the upper transistors UT1, and UT2. The number of lower transistors LT1, and LT2 and the number of upper transistors UT1, and UT2 may be varied depending on embodiments.

In some embodiments, the top transistors UT1 and UT2 may include a string select transistor, and the lower transistors LT1 and LT2 may include a ground select transistor. The gate lower lines LL1 and LL2 may be the gate electrodes of the lower transistors LT1 and LT2, respectively. The word lines WL may be the gate electrodes of memory cell transistors MCT, and the gate upper lines UL1, and UL2 may be the gate electrodes of the upper transistors UT1 and UT2, respectively.

The common source line CSL, the first and second gate lower lines LL1 and LL2, the word lines WL, the first and second gate upper lines UL1 and UL2 may be electrically connected to the decoder circuit 1110 through a first connection wiring 115 that extends from inside of the first structure 1100F to the second structure 1100S. The bit lines BL may be electrically connected to the page buffer 1120 through a second connection wirings 1125 that extend from inside of the first structure 1100F to the second structure 1100S.

In the first structure 1100F, the decoder circuit 1110 and the page buffer 1120 may perform control operations on at least one selection memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pad 1101 may be electrically connected to the logic circuit 1130 through an input/output connection wiring 1135 that extends from inside of the first structure 1100F to the second structure 1100S.

The controller 1200 may include a processor 1210, a NAND controller 1220, and a host interface 1230. Depending on embodiments, the electronic system 10000 may include a plurality of semiconductor devices 1100, and in this case, the controller 1200 may control a plurality of semiconductor devices 1100.

A processor 1210 may control the overall operation of electronic system 10000, including the controller 1200. The processor 1210 may operate according to a predetermined firmware and control the NAND controller 1220 to access the semiconductor device 1100. The NAND controller 1220 may include a NAND interface 1221 that processes communication with the semiconductor device 1100. Through the NAND interface 1221, control instructions for controlling the semiconductor device 1100, data to be written to the memory cell transistors MCT of the semiconductor device 1100, data to be read from the memory cell transistors MCT of the semiconductor device 1100, etc. may be transmitted. The host interface 1230 may provide a communication function between the electronic system 10000 and an external host. When receiving a control instruction from an external host through the host interface 1230, the processor 1210 may control the semiconductor device 1100 in response to the control instruction.

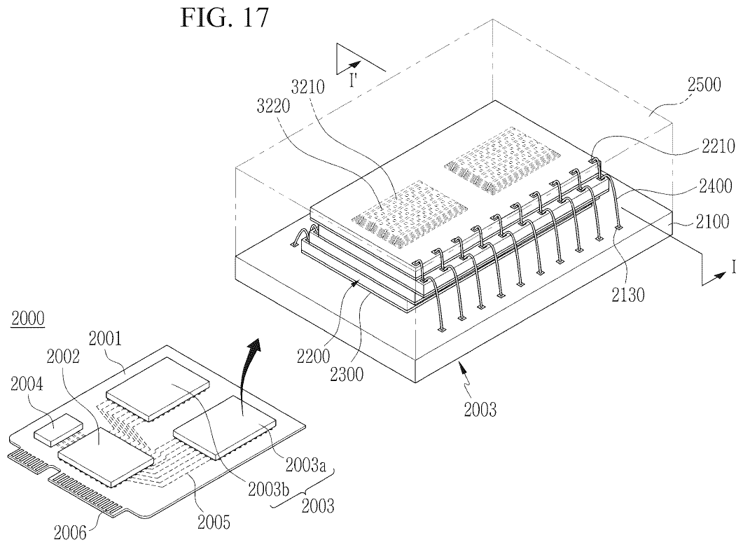

FIG. 17 is a perspective view schematically illustrating an electronic system including a semiconductor device according to some embodiments.

Referring to FIG. 17, the electronic system 2000 may include a main substrate 2001, a controller 2002 mounted on the main substrate 2001, one or more semiconductor packages 2003, and DRAM 2004. The semiconductor package 2003 and DRAM 2004 may be connected to the controller 2002 through a wiring pattern 2005 formed on the main substrate 2001.

The main substrate 2001 may include a connector 2006 including a plurality of pins to be coupled to the external host. In connector 2006, the number and arrangement of plurality of pins may vary depending on the communication interface between the electronic system 2000 and the external host. In some embodiments, the electronic system 2000 may communicate with an external host, according to any one of interfaces such as Universal Serial Bus (USB), Peripheral Component Interconnect Express (PCI-Express), Serial Advanced Technology Attachment (SATA), and M-Phy for Universal Flash Storage (UFS) and the like. In some embodiments, the electronic system 2000 may operate by power supplied from an external host through connector 2006. The electronic system 2000 may further include a PMIC (Power Management Integrated Circuit) distributing power supplied from the external host to the controller 2002 and the semiconductor package 2003.

The controller 2002 may record data in semiconductor package 2003 or read data from semiconductor package 2003, and may improve the operation speed of the electronic system 2000.

DRAM 2004 may be a buffer memory to alleviate the speed difference between the external host and the semiconductor package 2003 which is a data storage space. DRAM 2004 included in the electronic system 2000 may also operate as a kind of cache memory and may provide spaces for temporarily storing data during control operations on the semiconductor package 2003. In embodiments where the electronic system 2000 includes DRAM 2004, the controller 2002 may further include a DRAM controller for controlling DRAM 2004 in addition to a NAND controller for controlling semiconductor package 2003.

The semiconductor package 2003 may include the first and second semiconductor packages (2003a, 2003b) spaced apart from each other. Each of the first and second semiconductor packages (2003a, 2003b) may be a semiconductor package including a plurality of semiconductor chips 2200. Each of the first and second semiconductor packages (2003a, 2003b) may include a package substrate 2100, a semiconductor chip 2200 on the package substrate 2100, an adhesive layer 2300 disposed on a bottom surface of each semiconductor chip 2200, a connection structure 2400 electrically connecting connects the semiconductor chip 2200 and the package substrate 2100, and a molding layer 2500 covering the semiconductor chip 2200 and the connection structure 2400 on the package substrate 2100.

The package substrate 2100 may be a printed circuit board (PCB) including a package upper pad 2130. Each semiconductor chip 2200 may include an input/output pad 2210. The input/output pad 2210 may corresponds to the input/output pad 1101 of FIG. 16. Each semiconductor chip 2200 may include a gate stacking structure 3210 and a channel structure 3220. The semiconductor chip 2200 may include the semiconductor device described with reference to FIG. 9.

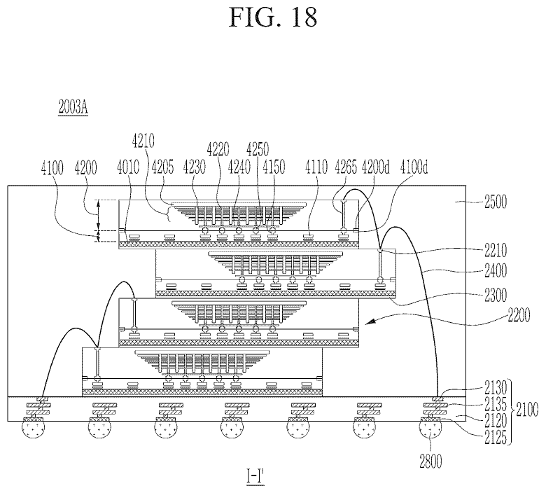

FIG. 18 is a cross-sectional view schematically illustrating a semiconductor device according to some embodiments.

Referring to FIG. 18, in the semiconductor package 2003A, each of the semiconductor chips 2200a may include a semiconductor substrate 4010, a first structure 4100 on the semiconductor substrate 4010, and a second structure 4200 junctioned with the first structure 4100 on the first structure 4100 by a wafer bonding method.

The first structure 4100 may include a peripheral circuit region including peripheral wiring 4110 and the first junction structure 4150. The second structure 4200 may include a common source line 4205, a gate stacking structure 4210 between the common source line 4205 and the first structure 4100, a channel structure 4220 and a separation structure 4230 that penetrate the gate stacking structure 4210, and second junction structures 4250 respectively electrically connected to the channel structure 4220 and the word line (see ‘WL’ in FIG. 16, hereinafter the same) of the gate stacking structure 4210. For example, the second junction structure 4250 may be respectively electrically connected to the channel structure 4220 and the word line WL through the bit line 4240 electrically connected to the channel structure 4220 and a gate connection wiring electrically connected to the word line WL. The first junction structure 4150 of the first structure 4100 and the second junction structure 4250 of the second structure 4200 may be junctioned with contacting each other. The junction portions of the first junction structure 4150 and the second junction structure 4250 may be formed of copper (Cu), for example.

In a semiconductor chip 2200a or semiconductor device according to some embodiments, a first dummy pattern 4100d positioned at an edge of the first structure 4100 to be exposed from a side surface of the first structure 4100, and a second dummy pattern 4200d positioned at an edge of the second structure 4200 to be exposed from a side surface of the first structure 4100 may be formed. Since the first dummy pattern 4100d and the second dummy pattern 4200d are junctioned with contacting each other, the junction force between the first structure 4100 and the second structure 4200 can be improved.

Each semiconductor chip 2200a may further include an input/output pad 2210 and input/output connection wiring 4265 below the input/output pad 2210. The input/output connection wiring 4265 may be electrically connected to a part of the second junction structure 4250.

In some embodiments, a plurality of semiconductor chips 2200 in semiconductor package 2003 may be electrically connected to each other by the connection structures 2400 such as bonding wire. As another example, the plurality of semiconductor chip 2200 or the plurality of parts of it may be electrically connected by a connection structure including a via electrode.

Although the embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

What is claimed is:

1. A semiconductor device comprising:
a first semiconductor chip comprising a first bonding pad and at least one first dummy pattern; and
a second semiconductor chip positioned on the first semiconductor chip, the second semiconductor chip comprising a second bonding pad and at least one second dummy pattern;
wherein:
the first bonding pad is in contact with the second bonding pad;
the first dummy pattern is in contact with the second dummy pattern;
the first dummy pattern is positioned at an edge of the first semiconductor chip and configured to be exposed from a side surface of the first semiconductor chip; and
the second dummy pattern is positioned at an edge of the second semiconductor chip and configured to be exposed from a side surface of the second semiconductor chip.

2. The semiconductor device of claim 1, wherein
in at least a part of an interface between the first semiconductor chip and the second semiconductor chip, the first dummy pattern and the second dummy pattern have no boundary.

3. The semiconductor device of claim 1, wherein
a melting point of the first dummy pattern and the second dummy pattern is equal to or lower than a melting point of the first bonding pad and the second bonding pad.

4. The semiconductor of claim 1, wherein:
the first dummy pattern is positioned at substantially the same level as the first bonding pad; and
the second dummy pattern is positioned at substantially the same level as the second bonding pad.

5. The semiconductor of claim 1, wherein:
the first dummy pattern comprises the same material as the first bonding pad; and
the second dummy pattern comprises the same material as the second bonding pad.

6. The semiconductor device of claim 1, wherein
the first dummy pattern and the second dummy pattern may be positioned continuously along edges of the first semiconductor chip and the second semiconductor chip, respectively.

7. The semiconductor device of claim 1, wherein
the at least one first dummy pattern and the at least one second dummy pattern may be positioned discontinuously along edges of the first semiconductor chip and the second semiconductor chip, respectively.

8. The semiconductor device of claim 1, wherein
a width of the first dummy pattern and a width of the second dummy pattern is 7 μm or more and 13 μm or less, respectively.

9. The semiconductor device of claim 1, wherein
a thickness of the first dummy pattern and a thickness of the second dummy pattern is 5 μm or more, respectively.

10. The semiconductor device of claim 1, wherein:
the first semiconductor chip further comprises first circuit elements, and first wiring layers electrically connected to the first circuit elements and the first bonding pad, and has a first central region where the first circuit elements, the first wiring layers and the first bonding pad are positioned, and a first peripheral area which surrounds the first central region and where the first dummy pattern is positioned;
the second semiconductor chip further includes second circuit elements, and second wiring layers electrically connected to the second circuit elements and the second bonding pad, and has a second central region where the second circuit elements, the second wiring layers and the second bonding pad are positioned, and a second peripheral area which surrounds the second central region and where the second dummy pattern is positioned; and
a distance between the first dummy pattern and the first central region is 10 μm or more and a distance between the second dummy pattern and the second central region is 10 μm or more.

11. A semiconductor device comprising:
a peripheral circuit chip comprising a plurality of first wiring layers, a plurality of first bonding pads electrically connected to the plurality of first wiring layers, and at least one first dummy pattern; and
a memory chip positioned on the peripheral circuit chip, the memory chip comprising a common source line, a plurality of word lines positioned between the common source line and the peripheral circuit chip, a plurality of channel structures penetrating the plurality of word lines, a plurality of second wiring layers electrically connected to the word lines and the plurality of channel structures, a plurality of second bonding pads electrically connected to the plurality of second wiring layers, and at least one second dummy pattern, wherein:
the plurality of first bonding pads contacts the plurality of second bonding pads;
the first dummy pattern contacts the second dummy pattern;
the first dummy pattern is positioned at an edge of the peripheral circuit chip and configured to be exposed from a side surface of the peripheral circuit chip; and
the second dummy pattern is positioned at an edge of the memory chip and configured to be exposed from a side surface of the memory chip.

12. The semiconductor device of claim 11, wherein
in at least a part of the interface between the peripheral circuit chip and the memory chip, the first dummy pattern and the second dummy pattern have no boundary.

13. The semiconductor device of claim 11, wherein:
the peripheral circuit chip has a first central region where the plurality of first wiring layers and the plurality of first bonding pads are positioned, and a first peripheral area which surrounds the first central region and where the first dummy pattern is positioned;
the memory chip has a second central region where the common source line, the plurality of word lines, the plurality of channel structures, the plurality of second wiring layers and the plurality of second bonding pads are positioned, and a second peripheral area which surrounds the second central region and where the second dummy pattern is positioned; and
a distance between the first dummy pattern and the first central region and a distance between the second dummy pattern and the second central region is 10 μm or more, respectively.

14. A semiconductor device manufacturing method, comprising:
preparing a first wafer comprising a first bonding pad and a first dummy pattern;
preparing a second wafer comprising a second bonding pad and a second dummy pattern;
bonding the first wafer and the second wafer so that the first bonding pad contacts the second bonding pad, and the first dummy pattern contacts the second dummy pattern; and
laser processing the first wafer and the second wafer along a scribe lane area,
wherein at least a part of each of the first dummy pattern and the second dummy pattern is positioned in the scribe lane area to be processed by the laser processing.

15. The semiconductor device manufacturing method of claim 14, wherein
at least a part of each of the first dummy pattern and the second dummy pattern is combined after melting during the laser processing.

16. The semiconductor device manufacturing method of claim 14, wherein
a part of the first dummy pattern remains in the first wafer, and a part of the second dummy pattern remains in the second wafer, after the laser processing.

17. The semiconductor device manufacturing method of claim 14, wherein
the first wafer and the second wafer are processed entirely in a direction of thickness of the first wafer and the second wafer during the laser processing.

18. The semiconductor device manufacturing method of claim 14, wherein:
during the laser processing, the laser processes the first wafer entirely in a thickness direction and further processes a part of the second wafer in the thickness direction; and
the semiconductor device manufacturing method further comprises blade processing a remaining part of the second wafer in the thickness direction.

19. The semiconductor device manufacturing method of claim 18, wherein
a thickness of the first wafer is smaller than a thickness of the second wafer.

20. The semiconductor device manufacturing method of claim 14, wherein
during the laser processing, a width of which the first wafer and the second wafer processed by the laser is less than 20 μm.
